(19) United States
(12) Patent Application Publication
(10) Pub. No.: US 2026/0351533 A1
(43) Pub. Date: Nov. 5, 2026

(54) PARASITIC PLASMA DETECTION DEVICE AND METHOD

(71) Applicant: ASM IP Holding B.V., Almere (NL)

(72) Inventor: Dinesh Hosamani, Apache Junction, AZ (US)

(21) Appl. No.: 19/661,860

(22) Filed: Apr. 29, 2026

Related U.S. Application Data
(60) Provisional application No. 63/799,012, filed on May 2, 2025.

(51) Int. Cl. H01J 37/32

(52) U.S. Cl. CPC H01J 37/32917; H01J 37/32798; H01J 2237/24564

(57) ABSTRACT

Devices for detecting a plasma, as well as reactor systems including devices for detecting a plasma and methods for detecting a plasma are disclosed. An exemplary device includes an ion collector and a meter configured to measure changes in one or more of current, electric charge, or electric potential difference. An exemplary device also includes a controller configured to produce one or more signals indicative of the presence of a parasitic plasma and/or the size and intensity of the parasitic plasma.

### CROSS-REFERENCE TO RELATED APPLICATIONS

This application claims priority to U.S. Provisional Patent Application Ser. No. 63/799,012 filed May 2, 2025 and titled PARASITIC PLASMA DETECTION DEVICE AND METHOD, the disclosure of which is hereby incorporated by reference in its entirety.

### FIELD

The disclosure generally relates to plasma detection devices, methods of detecting parasitic plasmas, and apparatuses including plasma detection devices. More particularly, examples of the disclosure relate to methods and devices that detect ions that may be generated from a parasitic plasma.

### BACKGROUND

In semiconductor fabrication, plasmas are used in a variety of processes and systems. For example, plasmas are often used to generate activated species that can be used in deposition, etch, or cleaning processes.

Some systems that use plasmas include reaction spaces between parallel electrodes, where a plasma is intended to be generated. However, parasitic plasmas are often generated in other spaces within the systems, such as exhaust systems or other cavities within the system. These parasitic plasmas may cause damage to components of the systems, generate unwanted particles that may cause defects on a substrate being processed, or cause process variations across a substrate being processed.

Parasitic plasmas may be detected through matching networks, temperature changes in system components, or using optical sensors configured to detect radiation emitted from the parasitic plasma. Such techniques may be slow to detect a plasma and/or may not detect weaker parasitic plasmas before significant damage is done to system components. Therefore, there exists a desire for improved parasitic plasma detection devices and systems, such as detection devices and systems that detect parasitic plasmas directly and/or before significant damage to system components occur.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to parasitic plasma detections devices, reactor systems including parasitic plasma detection devices, and methods for detecting a parasitic plasma. As set forth below, methods described herein may be used in the fabrication of electronic devices, such as semiconductor devices. Exemplary devices may be able to detect a parasitic plasma in a space by detecting the generation of ions. Exemplary reactor systems may include a detection device placed in a space where a parasitic plasma may be generated. Exemplary reactor systems may be configured to interlock or cease providing plasma (e.g., RF) power if a signal from the detection device exceeds a threshold value or exceeds a threshold value for a certain time period. Exemplary methods may detect a parasitic plasma using the detection devices or reactor systems described herein.

According to one or more embodiments, an exemplary device for detecting a plasma is provided. An exemplary device includes a faceplate, an ion collector, and a meter connected to the ion collector. An exemplary device is configured to detect the presence of (e.g., positive and/or negative) ions, such as ions produced by a plasma. The faceplate of an exemplary device may be configured to be mounted or connected to a (e.g., inner) wall of a reactor system, in a space where a parasitic plasma may be generated. The ion collector may extend through the faceplate and connect to the meter. The meter may be configured to measure at least one of current, electric charge, or electric potential difference. The ion collector may be configured to contact with ions generated by a parasitic plasma. When an ion contacts the ion collector, the meter may measure a change in at least one of current, electric charge, or electric potential difference. The meter may produce an output indicating the change in at least one of current, electric charge, or electric potential difference. The output may be indicative of the presence of a parasitic plasma that generates ions. An exemplary device may further include a controller that may convert the output from the meter to a signal indicative of a presence of the plasma or of the relative amount of ion generation.

An exemplary device may further include a grid and a generator connected to the grid. The grid may have a first portion extending through the faceplate to connect with the generator, and a second portion including a coil, a ring, or a series of (e.g., concentric) rings about an axis. The second portion may encircle or surround the ion collector. The generator may be disposed on the same side of the faceplate as the meter. The generator may be configured to produce at least one of an AC voltage, a positive DC voltage, or a negative DC voltage to the grid. In operation, the voltage generated to the grid may produce an electrical field that may trap and direct ions towards the ion collector.

According to one or more embodiments, an exemplary reactor system with parasitic plasma detection is provided. An exemplary reactor system includes a reaction chamber, a controller, a susceptor disposed in the reaction chamber, a reaction space that can be defined at least in part by a top surface of the susceptor, a secondary space proximate to the reaction space, and a detection device mounted to a wall in the secondary space. An exemplary reactor system may be configured to generate a plasma in the reaction space. An exemplary reactor system may be designed to only generate a plasma in the reaction space, though the exemplary reactor system may generate a parasitic plasma in the secondary space. The detection device is configured to detect the generation of ions in the secondary space. The detection device may be a detection device as described herein. The detection device may produce an output to the controller indicating the change in at least one of current, electric charge, or electric potential difference. The controller may be configured to interlock the reactor system or cease generating a plasma if an output from the detection device exceeds a threshold value.

According to one or more embodiments, an exemplary method of parasitic plasma detection is provided. Exemplary methods may detect a parasitic plasma and stop plasma generation and minimize damage done by a parasitic plasma. An exemplary method includes providing a reactor system including a reaction space and a secondary space proximate to the reaction space, providing a detection device in the secondary space, generating a plasma in the reaction space, and producing a signal from the detection device indicative of a presence of the parasitic plasma in the secondary space. The reactor system and the detection device may be a reactor system and a detection device as described herein.

An exemplary method may further include sending an output from the detection device to a controller. An exemplary method may further include interlocking the reactor system or ceasing the generation of the plasma if the output exceeds a threshold value.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates a device for detecting a plasma, in accordance with one or more embodiments of the disclosure;

FIG. 2 illustrates another device for detecting a plasma, in accordance with one or more embodiments of the disclosure;

FIG. 3 illustrates an example of a reactor system in accordance with one or more examples of the disclosure;

FIG. 4 illustrates a method for detecting a parasitic plasma in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to necessarily limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The illustrations presented herein are not meant to be actual views of any particular system, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium. In some cases, the substrate can include an oxide (e.g., silicon oxide).

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

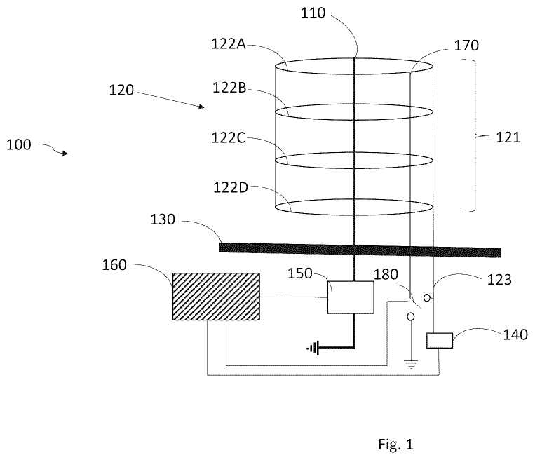

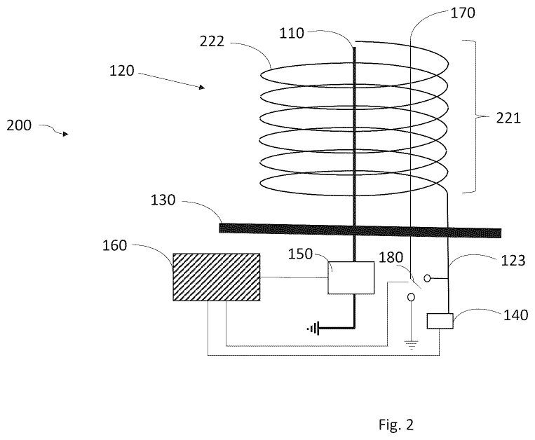

FIGS. 1 and 2 illustrate devices 100 and 200 for detecting a plasma in accordance with exemplary embodiments of the disclosure. Device 100 and device 200 each comprise an ion collector 110, a grid 120, a faceplate 130, a generator 140 connected to the grid 120, a meter 150, a controller 160, a modulator 170, and a switch 180 connected to the modulator 170. Device 200 also comprises an ion collector 110, a grid 120, a faceplate 130, a generator 140 connected to the grid 120, a meter 150, a controller 160, a modulator 170, and a switch 180 connected to the modulator 170. Device 200 is similar to device 100, except device 200 has a different second portion 221 of the grid 120 than device 100. Except where specifically noted, device 200 can have the same structure, components, functions, and configurations of device 100.

In some embodiments, the device 100 is configured to detect (e.g., positive and/or negative) ions generated from a plasma. In some embodiments, the device 100 is configured to produce an output indicating the number of ions detected. In some embodiments, the device 100 is configured to produce a signal indicative of the presence of a parasitic plasma. In some embodiments, the device 100 is configured to produce a signal indicative of the intensity or size of a parasitic plasma.

In some embodiments, the ion collector 110 comprises a conductive material, such as a metal. In some embodiments, the ion collector 110 comprises one or more of copper, silver, gold, steel, aluminum, and brass. In some embodiments, the ion collector 110 is a (e.g., straight) wire. The ion collector 110 extends through the faceplate 130 and is connected to the meter 150. In some embodiments, the ion collector 110 has (e.g., substantially) no voltage bias or is at (e.g., nearly) ground potential when not contacted by ions. In some embodiments, the ion collector 110 has (e.g., nearly) no net charge when not contacted by ions. In some embodiments, the ion collector 110 has (e.g., nearly) no net electric current when not contacted by ions. The ion collector 110 is configured to produce a current, a change in an electrical potential, or a change in its electric charge when it contacts an ion.

The meter 150 is configured to measure the change in current, electrical potential, or electric charge when an ion contacts the ion collector 110. The meter 150 may be a suitable meter that may measure change in current, electrical potential, or electric charge when an ion contacts the ion collector 110. For example, the meter 150 may be an electrometer. The meter 150 produces an output (e.g., to the controller 160) signifying the change in current, electrical potential, or electric charge. As such, the output may indicate the presence of ions, such as ions produced by a plasma. In some embodiments, the meter 150 is configured to measure positive changes in electric charge or electric potential and/or negative changes in electric charge or electric potential. In some embodiments, the meter 150 is further connected to ground. In some embodiments, the meter 150 comprises an amplifier configured to amplify an output.

Controller 160 comprises electronic circuitry and software to collect, store, and analyze the output from the meter 150. In some embodiments, controller 160 is configured to produce one or more signals based on the output from the meter 150. In some embodiments, the controller 160 comprises an amplifier configured to amplify an output from the meter 150. In some embodiments, controller 160 is configured to produce a first signal indicative if the change in current, electrical potential, or electric charge exceeds a first threshold value. In some embodiments, controller 160 is configured to produce a second signal indicative if the change in current, electrical potential, or electric charge exceeds a second threshold value across a first time period. In some embodiments, controller 160 is configured to produce a third signal indicating a rate of ion collection (and therefore, a rate of ion production from a plasma). In some embodiments, controller 160 is configured to send one or more of the first signal, second signal, or third signal to other components, such as other system components or to user interfaces.

In some embodiments, the device 100 does not comprise any solid material surrounding or shielding the ion collector 110 from its environment or from the space where the device is being used to detect a plasma (other than the grid 120 and the modulator 170). In some embodiments, the device does not comprise any solid material (other than the grid 120 and the modulator 170) blocking a line-of-sight from the ion collector 110 to the space from the space where the device is being used to detect a plasma. In some embodiments, the device does not comprise any solid material blocking a line-of-sight from the ion collector 110 to the space from where the device is being used to detect a plasma (other than the grid 120 and the modulator 170).

The grid 120 can surround a portion of the ion collector 110 (e.g., along an axis of the ion collector 110). The grid 120 does not (e.g., directly) contact the ion collector 110. The grid 120 may comprise a conductive material, such as a metal. Exemplary materials include copper, silver, gold, aluminum, steel, and brass. The grid 120 may comprise a first portion 123 and a second portion 121. In some embodiments, the second portion 121 comprises a ring or a series of (e.g., concentric) rings about an axis, such as rings 122A-D in FIG. 1. (Although only 4 rings are shown in FIG. 1, the grid 120 may comprise any suitable number of rings.) In some embodiments, the second portion 121 encircles the ion collector 110. In some embodiments, the ion collector 110 is disposed on an axis running through a center the second portion 121. In some embodiments, the ion collector 110 is disposed on an axis running through a center of each of the series of concentric rings 122A-D in FIG. 1. In other embodiments, the ion collector 110 is disposed on an axis running through a center of the coil 222 in FIG. 2. The first portion 123 of the grid 120 connects the second portion 121 of the grid 120 to a generator 140 and extends through the faceplate 130.

In some embodiments, the grid 220 comprises a second portion 221 comprising a coil, such as coil 222 illustrated in FIG. 2.

In some embodiments, the generator 140 is configured to apply a voltage bias to the grid 120. In some embodiments, the generator 140 is configured to produce at least one of an AC voltage, a positive DC voltage, or a negative DC voltage to the grid 120. In some embodiments, the generator 140 is configured to (e.g., periodically or manually) change a type of voltage produced (i.e., from a DC to an AC voltage or vice versa). In some embodiments, the generator 140 is configured to (e.g., periodically, continuously, or manually) change an amount and/or sign of the voltage produced. In some embodiments, the controller 160 is configured to control the amount, sign, type, and/or duration of the voltage produced by the generator 140. In some embodiments, the controller 160 is configured to control the amount, sign, type, and/or duration of the voltage produced by the generator 140 based on an output of the meter 150 or from a user input. In some embodiments, the positive DC voltage is between about 1 V and about 50 V, or between about 5 V and about 25 V, or between about 10 V and about 20 V. In some embodiments, the negative DC voltage is between about −1 V and about −50 V, or between about −5 V and about −25 V, or between about −10 V and about −20 V. In some embodiments, the AC voltage is between about 5 V and about 110 V, or between about 20 V and about 80 V, or between about 30 V and about 60 V. In some embodiments, the AC voltage has a frequency of about 30 Hz to about 100 Hz, or between about 50 Hz and 60 Hz.

While the generator 140 provides a voltage bias to the grid 120, a (e.g., relative) electric potential gradient is created between the grid 120 and the ion collector 110. Ions are either repelled or attracted to the ion collector 110, depending on the type of the ion and the sign of the voltage bias. For example, when a positive voltage bias is applied to the grid 120, the electric potential gradient between the grid 120 and the ion collector 110 will attract positive ions and repel negative ions to the ion collector 110. Similarly, when a negative voltage bias is applied to the grid 120, the electric potential gradient between the grid 120 and the ion collector 110 will attract negative ions and repel positive ions to the ion collector 110. In some embodiments, the grid 120 may be configured to direct ions to the ion collector 110 when a voltage is applied to the grid 120. In some embodiments, the grid 120 may be configured to trap ions inside the coil 222 or concentric rings 122A-D when a voltage is applied to the grid 120. In some embodiments, the grid 120 is configured to trap and/or direct positive ions to the ion collector 110 when a positive DC voltage is applied to the grid 120. In some embodiments, the grid 120 is configured to trap and direct negative ions to the ion collector 110 when a negative DC voltage is applied to the grid 120. In some embodiments, the grid 120 is configured to trap and direct both positive and negative ions to the ion collector 110 when an AC voltage is applied to the grid 120.

In some embodiments, the device 100 further comprises a modulator 170. In some embodiments, the modulator 170 comprises one or more wires. In some embodiments, the modulator comprises a conductive material, such as a metal. In some embodiments, the modulator 170 extends through the faceplate 130 and connects to a switch 180. In some embodiments, the switch 180 is configured to connect to a ground or to connect to the first portion 123 of the grid 120 and the generator 140. In some embodiments, the modulator is not (e.g., directly) connected to the grid 120 when the switch 180 is connected to ground. In some embodiments, the modulator is not (e.g., directly) connected to the second portion 121 (or 221) of the grid 120. In some embodiments, the device 100 is configured to modulate a strength and/or shape of the electrical potential gradient based on the state of the switch 180. When the switch connects to the first portion 123 of the grid 120, the generator 140 applies a voltage bias to the modulator 170. When the switch connects to ground, no voltage bias is applied to the modulator 170. In some embodiments, the switch 180 is connected to the controller 160. In some embodiments, the controller 160 is configured to change the state of the switch 180 based on user input, an output of the meter 150, or from a signal produced by the controller 160 and/or received from a user input. In some embodiments, the controller 160 is configured to change the state of the switch 180 is an output from the meter 150 exceeds a threshold value.

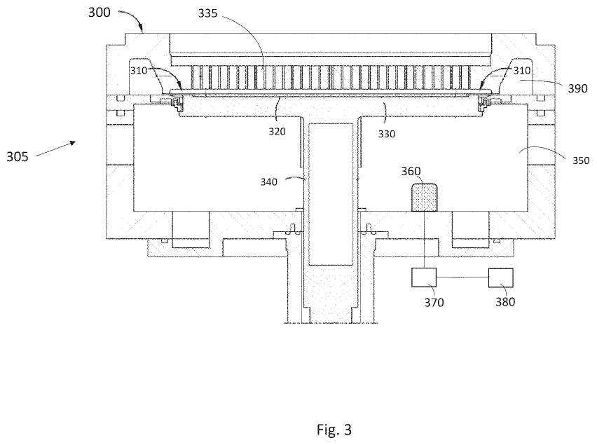

FIG. 3 illustrates a reactor system 300 for parasitic plasma detection in accordance with exemplary embodiments of the disclosure. Reactor system 300 includes a reaction chamber 305, a susceptor 330 configured to hold a substrate 320, a shaft 340 supporting the susceptor 330, an upper electrode 335, a reaction space 310, a secondary space 350, a detection device 360 including a meter 370, and a controller 380.

Reaction chamber 305 can include any suitable reaction chamber, such as an atomic layer deposition (ALD) or chemical vapor deposition (CVD) reaction chamber. By way of examples, reaction chamber 305 can form part of capacitively coupled plasma enhanced reactor system.

The detection device 360 may be any detection device as described herein. The detection device 360 is configured to detect ions, such as ions produced by a parasitic plasma. In some embodiments, reactor system 300 comprises a plurality of detection devices. In some embodiments, multiple detection devices are placed in the same space, such as the secondary space 350. In some embodiments, the reactor system is configured to detect parasitic plasmas in multiple spaces and detection devices are placed in multiple spaces, such as in an exhaust space 390.

In some embodiments, the susceptor 330 may comprise a lower electrode. In some embodiments, a reaction space 310 is defined, at least in part, by a top surface of the susceptor 330. In some embodiments, the reaction space 310 is defined, at least in part, by a lower surface of the upper electrode 335. During operation of the reactor system 300, a plasma may be generated in the reaction space 310, such as by applying plasma (e.g., RF) power to one or more of the susceptor 330 and the upper electrode 335.

In some embodiments, the reactor system 300 comprises a secondary space 350 proximate to the reaction space 310. In some embodiments, the secondary space 350 is defined at least in part by the lower surface of the susceptor 330 or is disposed beneath the susceptor 330. When plasma (e.g., RF) power is applied to the susceptor 330 and/or upper electrode 335 or when a plasma is generated in the reaction space 310, a parasitic plasma may be generated in the secondary space 350.

In some embodiments, the detection device 360 is disposed in the secondary space 350. In some embodiments, the detection device 360 comprises a faceplate that is connected to a wall in the secondary space 350. In some embodiments, the faceplate of the detection device 360 seals (e.g., vacuum-tight or nearly vacuum tight) to the wall in the secondary space 350. In some embodiments, the detection device 360 comprises an ion collector extending into the secondary space 350. In some embodiments, the detection device 360 comprises or is connected to a meter 370. The meter 370 may be the same or similar to meters described above. In some embodiments, the meter 370 is an electrometer. In some embodiments, the meter 370 is configured to measure changes in one or more of current, electric charge, or electric potential difference when ions contact the ion collector of the detection device 360. In some embodiments, the meter 370 produces an output (e.g., to the controller 380) signifying the change in current, electrical potential, or electric charge. As such, the output may indicate the presence of ions, such as ions produced by a plasma. In some embodiments, the meter 370 is configured to measure positive changes in electric charge or electric potential and/or negative changes in electric charge or electric potential.

In some embodiments, the detection device 360 is connected to a controller 380. In some embodiments, controller 380 may be same or similar to controllers described above. IN other embodiments, controller 380 may include additional hardware, software, and connections to control components of reactor system 300. In some embodiments, controller 380 can include modules such as a software or hardware component, e.g., a FPGA or ASIC, which performs certain tasks. A module can advantageously be configured to reside on the addressable storage medium of the control system and be configured to execute one or more processes or methods, as described herein. In some embodiments, controller 380 includes electronic circuitry and software to perform one or more of: selectively operate one or more generators, meters, and/or switches in the detection device; collecting, storing, and analyzing the output from the meter 370; produce one or more signals (e.g. to other components of the reactor system or to user interfaces) based on outputs from the meter 370; and to selectively operate other components included in the reactor system 300. In some embodiments, controller 380 is a component of the detection device 360. In some embodiments, controller 380 is a separate component from the detection device 360. In some embodiments, the reactor system 300 may comprise a plurality of controllers. Each controller of a plurality of controllers may perform one or more functions of controller 380 as described herein. In some embodiments, the controller 380 may be configured to perform sub-steps of methods as described herein.

In some embodiments, controller 380 is configured to produce one or more signals based on the output from the meter 370. In some embodiments, controller 380 is configured to produce a first signal indicative if the change in current, electrical potential, or electric charge exceeds a first threshold value. In some embodiments, controller 380 is configured to produce a second signal indicative if the change in current, electrical potential, or electric charge exceeds a second threshold value across a first time period. In some embodiments, the first time period has a duration between about 0.5 seconds and about 30 seconds, or about 1 second and about 15 seconds or about 3 seconds to about 10 seconds. In some embodiments, controller 380 is configured to produce a third signal indicating a rate of ion collection (and therefore, a rate of ion production from a plasma). In some embodiments, controller 380 is configured to send one or more of the first signal, second signal, or third signal to other components, such as other system components or to user interfaces. In some embodiments, controller 380 is configured to send a signal to interlock or cease plasma production (e.g., by ceasing provision of RF power to the one or more electrodes) if a signal exceeds a threshold value. In some embodiments, controller 380 is configured to send a signal to turn off a susceptor heater, turn off gas flows, or stop providing plasma power. In some embodiments, the controller is configured to receive outputs from a plurality of detection devices. In some embodiments, the controller is configured to send a signal to interlock or cease plasma production if an output from more than one detection device exceeds the first threshold value and/or exceeds the second threshold for the first time period.

Other configurations of reactor system 300 are possible, including different configurations of reaction spaces, electrodes, cavities, exhaust systems, and the like. Further, as a schematic representation of a system, many components have been omitted for simplicity of illustration, and such components may include, for example, various valves, manifolds, purifiers, heaters, containers, vents, and/or bypasses.

During operation of reactor system 300, substrates 320, such as semiconductor wafers, are transferred from, e.g., a substrate handling system to reaction chamber 305. Once substrate(s) are transferred to reaction chamber 305, one or more gases from gas sources (not shown) may be introduced into reaction chamber 305.

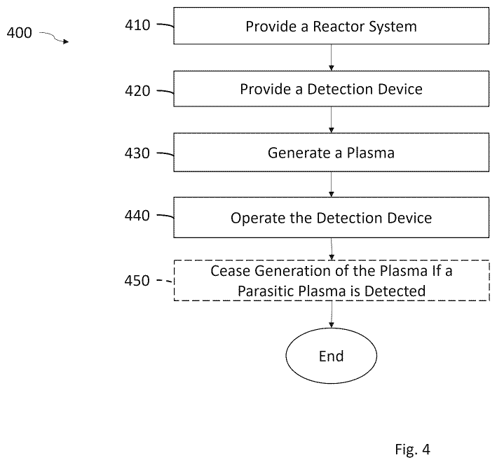

FIG. 4 illustrates a method 400 for detecting a parasitic plasma in a reactor system in accordance with exemplary embodiments of the disclosure. Method 400 comprises providing a reactor system 410, providing a detection device 420, generating a plasma 430, operating the detection device 440, and optionally ceasing generation of the plasma if a parasitic plasma is detected 450.

The reactor system provided during step 410 is configured to generate a plasma and may be any reactor system as described herein. The reactor system comprises a reaction space and a secondary space. In some embodiments, the reactor system is configured to generate a plasma in the reaction space. In some embodiments, the reactor system is designed to not generate a parasitic plasma in the secondary space, while working as intended.

Method 400 continues with providing a detection device 420. In some embodiments, providing a detection device 420 comprises providing a detection device in the secondary space. In some embodiments, providing a detection device 420 comprises providing a detection device in other spaces where detection of a plasma is desired, such as an exhaust system. In some embodiments, a plurality of detection devices is provided in one or more spaces. In some embodiments, the detection device is provided within a line-of-sight of a space where a plasma may be detected. In some embodiments, no solid material may be between the detection device and the space where a plasma is to be detected. The detection device is any suitable detection device as described herein. In some embodiments, the detection device is configured to detect ions. In some embodiments, the detection device comprises an ion collector and is configured to measure changes in one or more of current, electric charge, or electric potential difference when ions contact the ion collector.

Method 400 continues with generating a plasma 430. In some embodiments, generating a plasma 430 comprises providing RF power to one or more electrodes and one or more gases to a reaction space in the reactor system. As noted above, the reactor system may be designed to not generate a parasitic plasma in a secondary space while generating a plasma in a reaction space, while working as intended. However, the reactor system may be capable of generating a parasitic plasma in the secondary space while generating a plasma in a reaction space. In some embodiments, generating a plasma 430 comprises generating a parasitic plasma in a secondary space. Generating the plasma 430 comprises producing ions which may travel in the reaction space and/or secondary space. In some embodiments, generating a parasitic plasma in the secondary space causes ions to damage components of the reactor system.

Method 400 continues with operating the detection device 440. In some embodiments, operating the detection device 440 comprises measuring one or more of current, electric charge, or electric potential difference when ions contact the ion collector. In some embodiments, operating the detection device 440 comprises producing an output from a meter (e.g., to a controller) of changes in one or more of current, electric charge, or electric potential difference. In some embodiments, operating the detection device 440 comprises a controller collecting, storing, and/or analyzing the output from the meter. In some embodiments, operating the detection device 440 comprises the controller producing one or more signals based on the output from the meter. In some embodiments, operating the detection device 440 comprises the controller producing a first signal indicative if the change in current, electrical potential, or electric charge exceeds a first threshold value. The first threshold value may be an input from a user, a predetermined value, or a calculated value from other inputs, such as amount of plasma (e.g.) RF power provided to the electrodes. In some embodiments, operating the detection device 440 comprises the controller producing a second signal indicative if the change in current, electrical potential, or electric charge exceeds a second threshold value across a first time period. The second threshold value may be an input from a user, a predetermined value, or a calculated value from other inputs, such as amount of RF power provided to the electrodes. The first time period may be an input from a user, a predetermined value, or a calculated value from other inputs, such as amount of RF power provided to the electrodes. In some embodiments, the first time period is at least 0.5 seconds. In some embodiments, the first time period has a duration between about 0.5 seconds and about 30 seconds, or about 1 second and about 15 seconds or about 3 seconds to about 10 seconds. In some embodiments, operating the detection device 440 comprises the controller producing a third signal indicating a rate of ion collection (and therefore, a rate of ion production from a plasma). In some embodiments, operating the detection device 440 comprises the controller sending one or more of the first signal, second signal, or third signal to other components, such as other system components or to user interfaces. In some embodiments, operating the detection device comprises determining if a parasitic plasma is produced based on one or more of the signals from the controller.

In some embodiments, operating the detection device 440 comprises a generator of the detection device applying at least one of an AC voltage, a positive DC voltage, or a negative DC voltage to the grid of the detection device. In some embodiments, operating the detection device 440 comprises modifying the voltage applied to the grid. In some embodiments, the positive DC voltage is between about 1 V and about 50 V, or between about 5 V and about 25 V, or between about 10 V and about 20 V. In some embodiments, the negative DC voltage is between about −1 V and about −50 V, or between about −5 V and about −25 V, or between about −10 V and about −20 V. In some embodiments, the AC voltage is between about 5 V and about 110 V, or between about 20 V and about 80 V, or between about 30 V and about 60 V. In some embodiments, the AC voltage has a frequency of about 30 Hz to about 100 Hz, or between about 50 Hz and 60 Hz.

In some embodiments, operating the detection device 440 comprises changing the state of a switch of the detection device, wherein the switch is connected to a modulator and to ground or the grid. In some embodiments, operating the detection device 440 comprises the controller changing the state of the switch based on a signal from the controller.

Method 400 continues with optionally ceasing generation of the plasma if a parasitic plasma is detected 450. In some embodiments, ceasing generation of the plasma 450 comprises interlocking the reactor system. In some embodiments, ceasing generation of the plasma 450 comprises ceasing to provide RF power to the reactor system. The controller may be used to interlock the reactor system or control provision of RF power.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for detecting a parasitic plasma in a reactor system, the method comprising:
providing the reactor system comprising a reaction space and a secondary space proximate to the reaction space;
providing a detection device in the secondary space;
generating a plasma in the reaction space; and
producing a signal from the detection device indicative of a presence of the parasitic plasma in the secondary space, wherein the detection device is configured to detect ions.

2. The method of claim 1, wherein the detection device comprises:
an ion collector extending into the secondary space;
a faceplate, wherein the ion collector extends through the faceplate, and wherein the faceplate is configured to be attached to a wall of the secondary space; and
a meter configured to measure at least one of current, electric charge, or electric potential difference, wherein the meter is connected to the ion collector, and
wherein the detection device is configured to measure changes in one or more of current, electric charge, or electric potential difference when ions contact the ion collector.

3. The method of claim 2, wherein the detection device further comprises:
a grid comprising a first portion extending through the faceplate and a second portion comprising a coil or a series of concentric rings, wherein the second portion encircles the ion collector; and
a generator connected to the grid, wherein the generator is configured to produce at least one of an AC voltage, a positive DC voltage, or a negative DC voltage to the grid.

4. The method of claim 3, further comprising applying at least one of the AC voltage, the positive DC voltage, or the negative DC voltage to the grid,
wherein the grid is configured to trap and direct ions to the ion collector when a voltage is applied to the grid.

5. The method of claim 4, wherein at least one of the AC voltage or the negative DC voltage is applied to the grid.

6. The method of claim 1, wherein a top surface of a susceptor at least in part defines the reaction space and wherein the secondary space is disposed beneath the susceptor.

7. The method of claim 1, wherein the detection device produces a first signal indicating the presence of the parasitic plasma if a change in one or more of current, electric charge, or electric potential difference exceeds a first threshold value.

8. The method of claim 1, wherein the detection device produces a second signal indicating the presence of the parasitic plasma if a change in one or more of current, electric charge, or electric potential difference exceeds a second threshold value for a first time period.

9. The method of claim 1, wherein the detection device is connected to a controller, wherein the controller is configured to stop generating the plasma in the reaction space if a change in one or more of current, electric charge, or electric potential difference exceeds a first threshold value.

10. The method of claim 3, wherein the detection device further comprises a modulator extending through the faceplate and connected to a switch, and wherein the detection device is connected to a controller, wherein the controller is configured to change a status of the switch if a change in one or more of current, electric charge, or electric potential difference exceeds a second threshold value.

11. The method of claim 1, comprising providing a plurality of detection devices in the secondary space.

12. A reactor system with parasitic plasma detection, the reactor system comprising:
a reaction chamber;
a susceptor disposed in the reaction chamber;
a reaction space, wherein the reaction space is at least in part defined by a top surface of the susceptor;
a secondary space disposed beneath the susceptor; and
a detection device mounted to a wall in the secondary space, wherein the detection device is configured to detect a parasitic plasma in the secondary space, wherein the detection device comprises an ion collector extending into the secondary space, and wherein the detection device is configured to measure changes in one or more of current, electric charge, or electric potential difference when ions contact the ion collector.

13. The reactor system of claim 12, wherein the detection device further comprises:
a faceplate connected to the wall, wherein the faceplate seals to the wall, wherein the ion collector extends through the faceplate; and
a meter configured to measure at least one of current, electric charge, or electric potential difference, wherein the meter is connected to the ion collector.

14. The reactor system of claim 13, wherein the detection device further comprises:
a grid comprising a first portion extending through the faceplate and a second portion comprising a coil or a series of concentric rings, wherein the second portion encircles the ion collector; and
a generator connected to the grid, wherein the generator is configured to produce at least one of an AC voltage, a positive DC voltage, or a negative DC voltage to the grid.

15. The reactor system of claim 12, further comprising a controller connected to the detection device, wherein the controller is configured to interlock the reactor system if a signal from the detection device exceeds a threshold value.

16. A device for detecting a plasma, the device comprising:
a faceplate;
an ion collector comprising a conductive material, wherein the ion collector extends through the faceplate;
a grid comprising a first portion extending through the faceplate and a second portion comprising a coil or a series of concentric rings, wherein the second portion encircles the ion collector;
a meter configured to measure at least one of current, electric charge, or electric potential difference, wherein the meter is connected to the ion collector; and
a generator connected to the grid, wherein the generator is configured to produce at least one of an AC voltage, a positive DC voltage, or a negative DC voltage to the grid,
wherein the device is configured to detect ions generated from the plasma.

17. The device of claim 16, wherein the ion collector is disposed along an axis running through a center of each of the series of concentric rings or a center of the coil.

18. The device of claim 16, further comprising a controller configured to convert an output from the meter to a signal indicative of a presence of the plasma.

19. The device of claim 16, wherein the generator is configured to produce at least one of the AC voltage or the negative DC voltage to the grid.

20. The device of claim 16, further comprising a modulator extending through the faceplate and connected to a switch.
